(19) United States
(12) Patent Application Publication
(10) Pub. No.: US 2026/0156824 A1
(43) Pub. Date: Jun. 4, 2026

(54) SEMICONDUCTOR DEVICE AND METHOD OF MANUFACTURING THE SAME

(71) Applicant: Samsung Electronics Co., Ltd., Suwon-si (KR)

(72) Inventors: Hyesong JEON, Suwon-si (KR); Soojung PARK, Suwon-si (KR); Ik Soo KIM, Suwon-si (KR); Hyeju NA, Suwon-si (KR); Jaebeom PARK, Suwon-si (KR)

(21) Appl. No.: 19/400,471

(22) Filed: Nov. 25, 2025

(30) Foreign Application Priority Data
Dec. 2, 2024 (KR) 10-2024-0176830

(51) Int. Cl. H10B 43/27; H10B 43/10; H10B 43/35

(52) U.S. Cl. CPC H10B 43/27; H10B 43/10; H10B 43/35

(57) ABSTRACT

A method of manufacturing a semiconductor device that includes a first mold structure including first insulating layers and third insulating layers which are alternately provided on a substrate, first channel holes penetrating the first mold structure, and a first sacrificial layer formed in the first channel holes. A second sacrificial layer filling the first channel holes is formed on the first sacrificial layer, a second mold structure including second insulating layers and fourth insulating layers alternately provided on the first mold structure is formed, and second channel holes penetrating the second mold structure are formed. The first and second sacrificial layers in the first channel holes are removed through the second channel holes, and a vertical structure is formed in the first and second channel holes. The first sacrificial layer includes a carbon nitride layer, and the second sacrificial layer includes a carbon layer.

### CROSS-REFERENCE TO RELATED APPLICATIONS

This U.S. non-provisional patent application claims priority under 35 U.S.C. § 119 of Korean Patent Application No. 10-2024-0176830, filed on Dec. 2, 2024, the entire contents of which are hereby incorporated by reference.

### BACKGROUND

A semiconductor device capable of storing a large amount of data is demanded in an electronic system which requires data storage. Accordingly, research is being carried out to increase data storage capacity of a semiconductor device. For example, as one of methods for increasing data storage capacity of a semiconductor device, a semiconductor device including three-dimensionally arranged memory cells instead of two-dimensionally arranged memory cells is being proposed.

### SUMMARY

In general, the present disclosure is directed toward a semiconductor device and a method of manufacturing a semiconductor device with improved yield and reliability.

According to some implementations, the present disclosure is directed to a method of manufacturing a semiconductor device that includes forming a first mold structure including first insulating layers and third insulating layers which are alternately provided on a substrate, forming first channel holes penetrating the first mold structure, forming a first sacrificial layer in the first channel holes, forming a second sacrificial layer filling the first channel holes on the first sacrificial layer, forming a second mold structure including second insulating layers and fourth insulating layers which are alternately provided on the first mold structure, forming second channel holes penetrating the second mold structure, removing the first and second sacrificial layers in the first channel holes through the second channel holes, and forming a vertical structure in the first and second channel holes, wherein the first sacrificial layer includes a carbon nitride layer, and the second sacrificial layer includes a carbon layer.

According to some implementations, the present disclosure is directed to a method of manufacturing a semiconductor device that includes forming a first mold structure including first insulating layers and third insulating layers which are alternately provided on a substrate, forming first channel holes penetrating the first mold structure, forming sacrificial patterns in the first channel holes, forming a second mold structure including second insulating layers and fourth insulating layers which are alternately provided on the first mold structure, forming second channel holes penetrating the second mold structure, removing the sacrificial patterns in the first channel holes through the second channel holes, and forming a vertical structure in the first and second channel holes, wherein the forming of the sacrificial patterns includes a first deposition process of supplying a nitrogen source and a carbon source, and a second deposition process of supplying the carbon source without supplying the nitrogen source.

According to some implementations, the present disclosure is directed to a semiconductor device that includes a first gate stack structure and a second gate stack structure which are sequentially provided on a substrate, the first and second gate stack structures each including electrodes and insulating layers which are alternately stacked, vertical structures penetrating the first and second gate stack structures, the vertical structures each including a vertical channel pattern and an information storage layer, and a residual sacrificial layer which is provided between the vertical structures and an uppermost insulating layer among insulating layers of the first gate stack structure, wherein the residual sacrificial layer includes a carbon nitride layer.

According to some implementations, the present disclosure is directed to a residual sacrificial layer that may have a shape of a ring or a partial shape of a ring surrounding an outer side surface of the vertical structures in a plan view.

According to some implementations, the present disclosure is directed to a vertical structure that may include a step portion of which a diameter discontinuously changes between the first gate stack structure and the second gate stack structure, and a residual sacrificial layer that may be provided to be adjacent to the step portion.

According to some implementations, the present disclosure is directed to a carbon content of a residual sacrificial layer that may be about 30 at % to about 70 at %, and a nitrogen content of the residual sacrificial layer that may be about 30 at % to about 70 at %.

According to some implementations, the present disclosure is directed to a residual sacrificial layer that may be an amorphous layer.

### BRIEF DESCRIPTION OF THE FIGURES

Example implementations will be more clearly understood from the following detailed description, taken in conjunction with the accompanying drawings.

FIG. 1 is a diagram schematically illustrating an example of an electronic system including a semiconductor memory element according to some implementations.

FIG. 2 is a perspective view schematically illustrating an example of an electronic system including a semiconductor memory element according to some implementations.

FIGS. 3 and 4 are cross-sectional views taken along lines I-I′ and II-II′ in FIG. 2 schematically illustrating examples of semiconductor packages according to some implementations.

FIG. 5 is a plan view illustrating an example of a semiconductor memory element according to some implementations.

FIG. 6 is a cross-sectional view taken along line A-A′ of FIG. 5 according to some implementations.

FIG. 7 is an enlarged view of region S of FIG. 6 according to some implementations.

FIG. 8 is a process flowchart illustrating an example of a method of manufacturing a semiconductor device according to some implementations.

FIGS. 9 to 13, 15, 16, 18, and 19 are cross-sectional views taken along line A-A′ of FIG. 5, for describing an example of a method of manufacturing a semiconductor device according to some implementations.

FIG. 14 is an enlarged view of region Q of FIG. 13 according to some implementations.

FIG. 17 is an enlarged view of region R of FIG. 16 according to some implementations.

### DETAILED DESCRIPTION

Hereinafter, a three-dimensional semiconductor memory device, a method of manufacturing the same, and an electronic system including the same according to embodiments of the inventive concept will be described in detail with reference to the drawings.

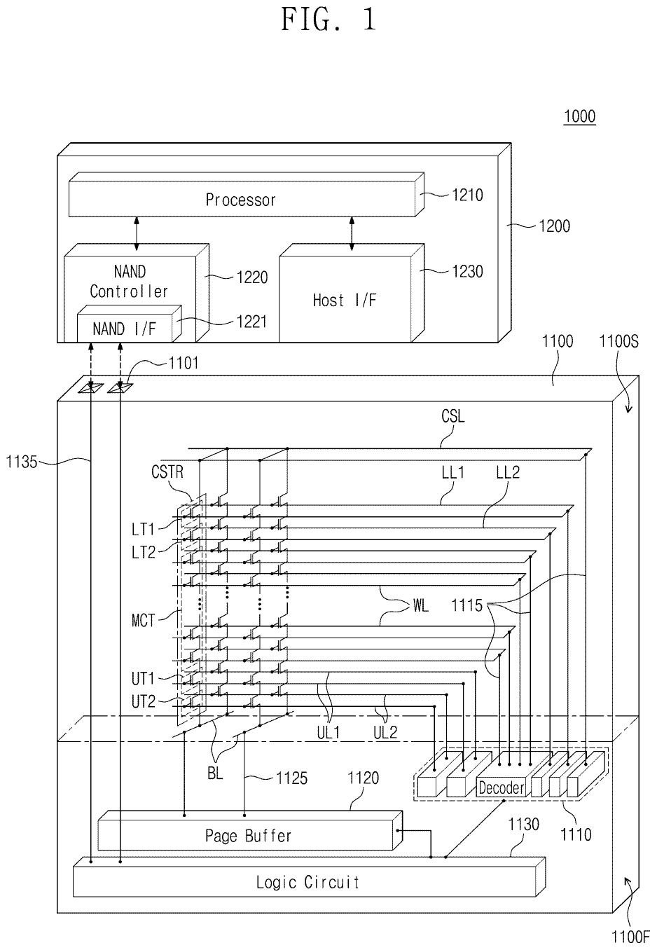

FIG. 1 is a diagram schematically illustrating an example of an electronic system including a three-dimensional semiconductor memory device according to some implementations. In FIG. 1, an electronic system 1000 may include a three-dimensional semiconductor memory device 1100 and a controller 1200 electrically connected to the three-dimensional semiconductor memory device 1100. The electronic system 1000 may be a storage device including one or more three-dimensional semiconductor memory devices 1100 or an electronic device including the storage device. For example, the electronic system 1000 may be a solid state drive (SSD) device, universal serial bus (USB), a computing system, a medical device, or a communication device, which includes one or more three-dimensional semiconductor memory devices 1100.

The three-dimensional semiconductor memory device 1100 may be a nonvolatile memory device, and for example, may be a three-dimensional NAND flash memory device to be described later. The three-dimensional semiconductor memory device 1100 may include a first region 1100F and a second region 1100S on the first region 1100F. However, in some implementations, the first region 1100F may be disposed beside the second region 1100S. The first region 1100F may be a peripheral circuit region including a decoder circuit 1110, a page buffer 1120, and a logic circuit 1130. The second region 1100S may be a memory cell region including bit lines BL, a common source line CSL, word lines WL, first lines LL1 and LL2, second lines UL1 and UL2, and memory cell strings CSTR between the bit lines BL and the common source line CSL.

In the second region 1100S, each of the memory cell strings CSTR may include first transistors LT1 and LT2 adjacent to the common source line CSL, second transistors UT1 and UT2 adjacent to the bit lines BL, and a plurality of memory cell transistors MCT arranged between the first transistors LT1 and LT2 and the second transistors UT1 and UT2. The number of the first transistors LT1 and LT2 and the number of the second transistors UT1 and UT2 may vary according to embodiments. The memory cell strings CSTR may be located between the common source line CSL and the first region 1100F.

For example, the second transistors UT1 and UT2 may include a string selection transistor, and the first transistors LT1 and LT2 may include a ground selection transistor. The first lines LL1 and LL2 may be gate electrodes of the first transistors LT1 and LT2. The word lines WL may be gate electrodes of the memory cell transistors MCT, and the second lines UL1 and UL2 may be gate electrodes of the second transistors UT1 and UT2.

The common source line CSL, the first lines LL1 and LL2, the word lines WL, and the second lines UL1 and UL2 may be electrically connected to the decoder circuit 1110 through first connection lines 1115 extending in the first region 1100F to the second region 1100S. The bit lines BL may be electrically connected to the page buffer 1120 through second connection lines 1125 extending in the first region 1100F to the second region 1100S.

In the first region 1100F, the decoder circuit 1110 and the page buffer 1120 may execute a control operation for at least one selected memory cell transistor among the plurality of memory cell transistors MCT. The decoder circuit 1110 and the page buffer 1120 may be controlled by the logic circuit 1130. The three-dimensional semiconductor memory device 1100 may communicate with the controller 1200 through an input/output pad 1101 electrically connected to the logic circuit 1130. The input/output pad 1101 may be electrically connected to the logic circuit 1130 through an input/output connection line 1135 extending in the first region 1100F to the second region 1100S.

The controller 1200 may include a processor 1210, a NAND controller 1220, and a host interface 1230. According to some implementations, the electronic system 1000 may include a plurality of three-dimensional semiconductor memory devices 1100, and in this case, the controller 1200 may control the plurality of three-dimensional semiconductor memory devices 1100.

The processor 1210 may control an overall operation of the electronic system 1000 including the controller 1200. The processor 1210 may operate according to predetermined firmware and control the NAND controller 1220 to access the three-dimensional semiconductor memory device 1100. The NAND controller 1220 may include a NAND interface 1221 which processes communication with the three-dimensional semiconductor memory device 1100. A control command for controlling the three-dimensional semiconductor memory device 1100, data to be written to the memory cell transistors MCT of the three-dimensional semiconductor memory device 1100, data to be read from the memory cell transistors MCT of the three-dimensional semiconductor memory device 1100, etc., may be transmitted through the NAND interface 1221. The host interface 1230 may provide a function of communication between the electronic system 1000 and an external host. When a control command is received from the external host through the host interface 1230, the processor 1210 may control the three-dimensional semiconductor memory device 1100 in response to the control command.

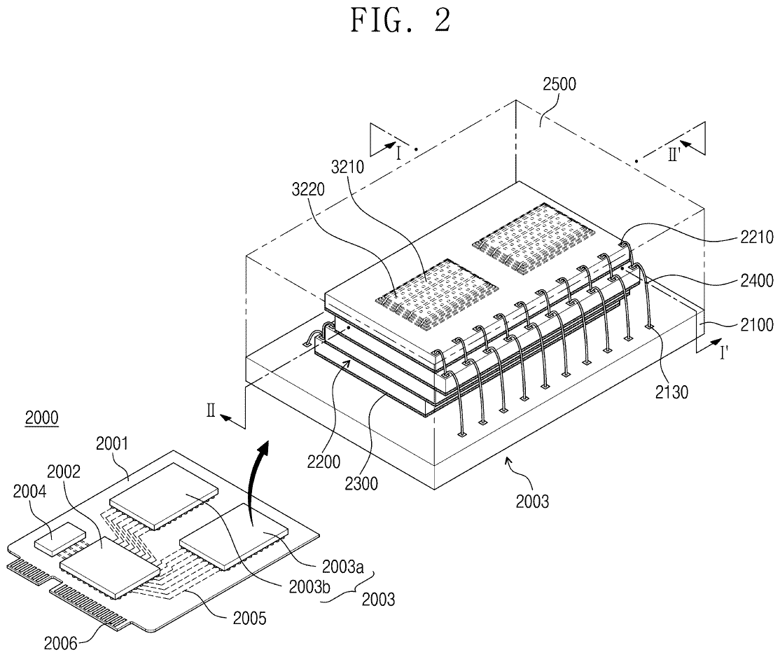

FIG. 2 is a perspective view schematically illustrating an example of an electronic system including a three-dimensional semiconductor memory device according to some implementations. In FIG. 2, an electronic system 2000 may include a main board 2001, a controller 2002 mounted on the main board 2001, one or more semiconductor packages 2003 and a DRAM 2004. The semiconductor package 2003 and the DRAM 2004 may be connected to the controller 2002 by wiring patterns 2005 provided to the main board 2001.

The main board 2001 may include a connector 2006 including a plurality of pins which are coupled to an external host. The number and arrangement of the plurality of pins in the connector 2006 may vary according to communication interface between the electronic system 2000 and the external host. For example, the electronic system 2000 may communicate with the external host according to any one of interfaces such as universal serial bus (USB), peripheral component interconnect express (PCI-express), serial advanced technology attachment (SATA), and M-Phy for universal flash storage (UFS). For example, the electronic system 2000 may operate by power supplied from the external host through the connector 2006. The electronic system 2000 may further include a power management integrated circuit (PMIC) which distributes power supplied from the external host to the controller 2002 and the semiconductor package 2003.

The controller 2002 may write data to or read data from the semiconductor package 2003 and improve operation speed of the electronic system 2000.

The DRAM 2004 may be a buffer memory for alleviating a difference in speed between an external host and the semiconductor package 2003 which is data storage space. The DRAM 2004 included in the electronic system 2000 may also operate as a kind of cache memory and provide a space for temporary data storage in a control operation for the semiconductor package 2003. In a case in which the DRAM 2004 is included in the electronic system 2000, the controller 2002 may further include a DRAM controller for controlling the DRAM 2004 in addition to a NAND controller for controlling the semiconductor package 2003.

The semiconductor package 2003 may include first and second semiconductor packages 2003a and 2003b spaced apart from each other. The first and second semiconductor packages 2003a and 2003b may each be a semiconductor package including a plurality of semiconductor chips 2200. The first and second semiconductor packages 2003a and 2003b may each include a package substrate 2100, semiconductor chips 2200 on the package substrate 2100, adhesive layers 2300 disposed on lower surfaces of the semiconductor chips 2200, respectively, connection structures 2400 electrically connecting the semiconductor chips 2200 and the package substrate 2100, and a molding layer 2500 covering the semiconductor chips 2200 and the connection structures 2400 on the package substrate 2100.

The package substrate 2100 may be a printed circuit board including package upper pads 2130. Each of the semiconductor chips 2200 may include input/output pads 2210. The input/output pads 2210 may each correspond to the input/output pad 1101 of FIG. 1. The semiconductor chips 2200 may each include gate stack structures 3210 and memory channel structures 3220. The semiconductor chips 2200 may each include a three-dimensional semiconductor memory device to be described later.

The connection structures 2400 may be, for example, bonding wires electrically connecting the input/output pads 2210 and the package upper pads 2130. Accordingly, in each of the first and second semiconductor packages 2003a and 2003b, the semiconductor chips 2200 may be electrically connected to each other in a wire bonding method and may be electrically connected to the package upper pads 2130 of the package substrate 2100. According to some implementations, in each of the first and second semiconductor packages 2003a and 2003b, the semiconductor chips 2200 may be electrically connected to each other by a through silicon via instead of the connection structures 2400 in a wire bonding method.

In some implementations, the controller 2002 and the semiconductor chips 2200 may be included in one package. The controller 2002 and the semiconductor chips 2200 may be mounted on a separate interposer substrate different from the main board 2001, and may be connected to each other by a line provided to the interposer substrate.

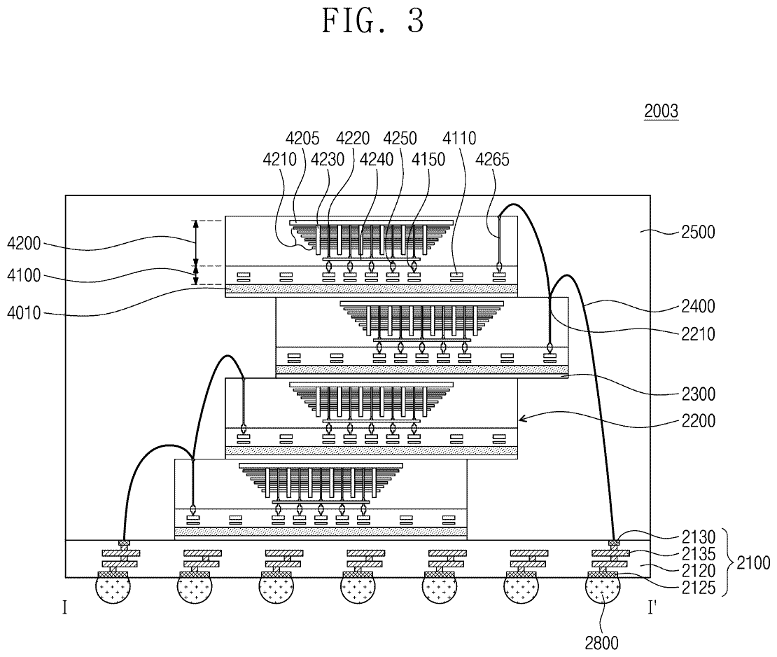

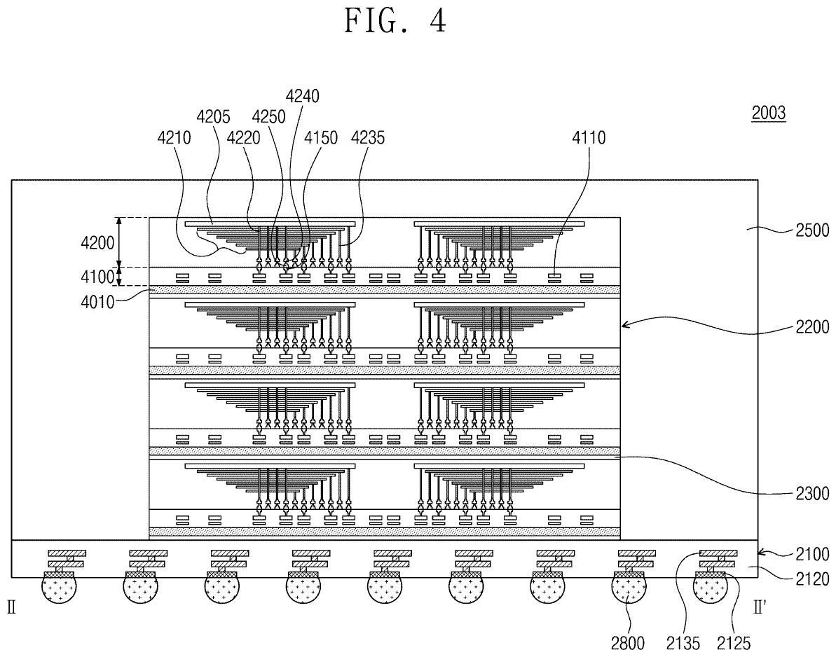

FIGS. 3 and 4 are cross-sectional views taken along lines I-I′ and II-II′ schematically illustrating examples of semiconductor packages according to some implementations. In FIGS. 3 and 4, the semiconductor package 2003 may include the package substrate 2100, the plurality of semiconductor chips 2200 on the package substrate 2100, and the molding layer 2500 covering the package substrate 2100 and the semiconductor chips 2200.

The package substrate 2100 may include a package substrate body portion 2120, upper pads 2130 disposed on or exposed through an upper surface of the package substrate body portion 2120, lower pads 2125 disposed on or exposed through a lower surface of the package substrate body portion 2120, and internal lines 2135 electrically connecting the upper pads 2130 and the lower pads 2125 inside the package substrate body portion 2120. The upper pads 2130 may be electrically connected to the connection structures 2400. The lower pads 2125 may be connected to the wiring patterns 2005 of the main board 2001 of the electronic system 2000 shown in FIG. 2 through conductive connection portions 2800.

In FIGS. 2 and 3, one sidewall of each of the semiconductor chips 2200 may not be aligned with each other, and another sidewall of each of the semiconductor chips 2200 may be aligned with each other. The semiconductor chips 2200 may be electrically connected to each other by the connection structures 2400 in a form of bonding wires. Each of the semiconductor chips 2200 may include substantially the same components.

The semiconductor chips 2200 may each include a semiconductor substrate 4010, a first structure 4100 on the semiconductor substrate 4010, and a second structure 4200 on the first structure 4100. The second structure 4200 may be coupled to the first structure 4100 in a wafer bonding manner.

The first structure 4100 may include peripheral circuit lines 4110 and first bonding pads 4150. The second structure 4200 may include a common source line 4205, a gate stack structure 4210 between the common source line 4205 and the first structure 4100, memory channel structures 4220 and separation structures 4230 penetrating the gate stack structure 4210, and second bonding pads 4250 electrically connected to the word lines WL (see FIG. 1) of the gate stack structure 4210 and the memory channel structures 4220. For example, the second bonding pads 4250 may be electrically connected to the memory channel structures 4220 and the word lines WL (see FIG. 1) through bit lines 4240 electrically connected to the memory channel structures 4220 and gate connection lines 4235 electrically connected to the word lines WL (see FIG. 1). The first bonding pads 4150 of the first structure 4100 and the second bonding pads 4250 of the second structure 4200 may be in contact with each other and may be coupled to each other. Coupled portions of the first bonding pads 4150 and the second bonding pads 4250 may include, for example, copper (Cu).

The semiconductor chips 2200 may each further include the input/output pad 2210 and an input/output connection line 4265 below the input/output pad 2210. The input/output connection line 4265 may be electrically connected to some of the second bonding pads 4250 and some of the peripheral circuit lines 4110.

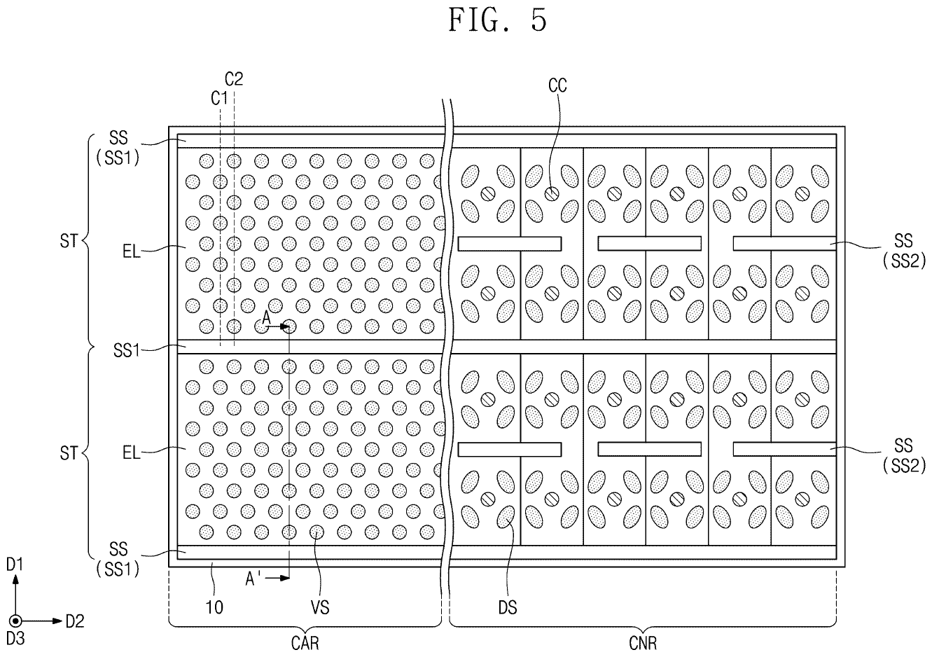

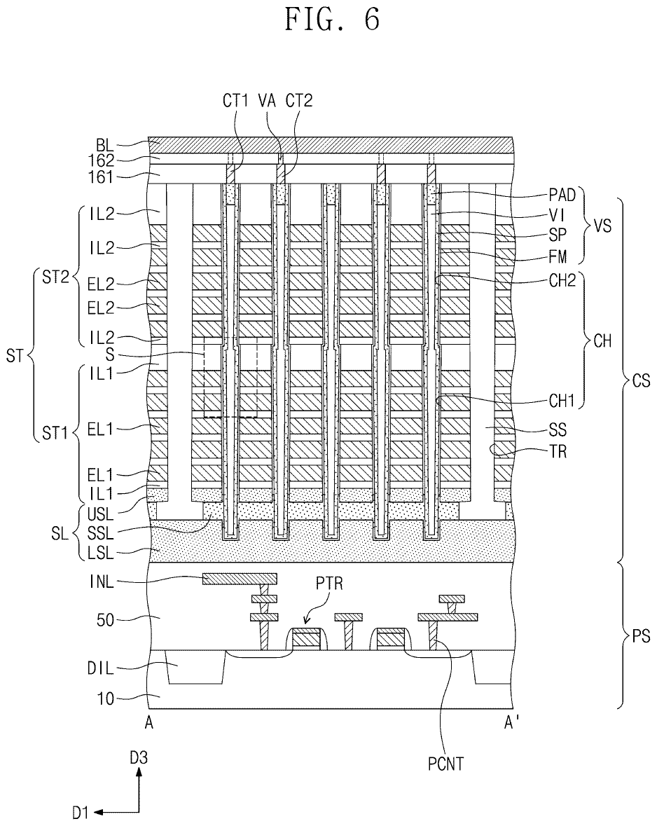

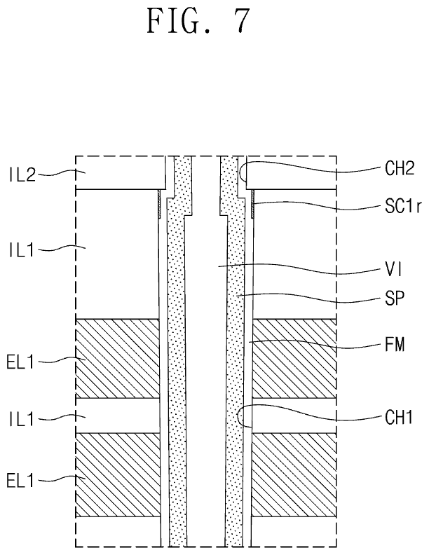

FIG. 5 is a plan view illustrating an example of a semiconductor memory element according to some implementations. FIG. 6 is a cross-sectional view taken along line A-A′ of FIG. 5 according to some implementations. FIG. 7 is an enlarged view of region S of FIG. 6 according to some implementations.

In FIGS. 5 to 7, a peripheral circuit structure PS including peripheral transistors PTR may be disposed on a first substrate 10. A cell array structure CS including gate stack structures ST may be disposed on the peripheral circuit structure PS. The first substate 10 may be a silicon substrate, a silicon-germanium substrate, a germanium substrate, or a single-crystalline epitaxial layer which is grown on a single-crystalline silicon substrate. The first substrate 10 may include active regions defined by an element isolation layer D1L. The peripheral transistors PTR may constitute a decoder circuit, a page buffer, a logic circuit, and the like as described above.

The peripheral circuit structure PS may include lower lines INL provided on the peripheral transistors PTR, and a first interlayer insulating layer 50 covering the peripheral transistors PTR and the lower lines INL. A peripheral contact PCNT electrically connecting the lower line INL and the peripheral transistor PTR may be provided between the lower line INL and the peripheral transistor PTR. The first interlayer insulating layer 50 may include insulating layers stacked as multiple layers. For example, the first interlayer insulating layer 50 may include a silicon oxide layer, a silicon nitride layer, a silicon oxynitride layer, and/or a low-k layer.

The cell array structure CS may be provided on the first interlayer insulating layer 50 of the peripheral circuit structure PS. Hereinafter, the cell array structure CS will be described in more detail. A second substrate SL may be provided on the first interlayer insulating layer 50. The second substrate SL may support the gate stack structures ST provided thereon.

The second substrate SL may include a lower semiconductor layer LSL, a source semiconductor layer SSL, and an upper semiconductor layer USL, which are sequentially stacked. The lower semiconductor layer LSL, the source semiconductor layer SSL, and the upper semiconductor layer USL may each include a semiconductor material (for example, at least one of silicon (Si), germanium (Ge), silicon germanium (SiGe), gallium arsenide (GaAs), indium gallium arsenide (InGaAs), aluminum gallium arsenide (AlGaAs), or mixture thereof). The lower semiconductor layer LSL, the source semiconductor layer SSL, and the upper semiconductor layer USL may each be single-crystalline, amorphous, and/or polycrystalline. For example, the lower semiconductor layer LSL, the source semiconductor layer SSL, and the upper semiconductor layer USL may each include an n-type polysilicon layer doped with impurities. The lower semiconductor layer LSL, the source semiconductor layer SSL, and the upper semiconductor layer USL may have impurity concentrations different from each other. For example, an impurity concentration of the source semiconductor layer SSL may be higher than an impurity concentration of each of the lower and upper semiconductor layers LSL and USL.

The second substrate SL may include a cell array region CAR and a connection region CNR as shown in FIG. 5. The cell array region CAR may be provided at a center of the second substrate SL. The connection region CNR may be disposed on at least one side of the cell array region CAR. The lower semiconductor layer LSL and the upper semiconductor layer USL may be connected to each other by the source semiconductor layer SSL.

The gate stack structures ST may each include electrodes EL stacked in a direction (that is, a third direction D3) vertical to the second substrate SL. For example, the gate stack structure ST may include a first gate stack structure ST1 and a second gate stack structure ST2 on the first gate stack structure ST1. Hereinafter, descriptions will be provided on the basis of two gate stack structures, but alternatively, three or more gate stack structures may be provided. The first gate stack structure ST1 may include first insulating layers IL1 by which stacked first electrodes EL1 are spaced apart from each other. The second gate stack structure ST2 may include second insulating layers IL2 and second electrodes EL2 which are alternately stacked. The first insulating layers IL1 and the first electrodes EL1 of the first gate stack structure ST1 may be alternately stacked in the third direction D3. The second insulating layers IL2 and the second electrodes EL2 of the second gate stack structure ST2 may be alternately stacked in the third direction D3. The first insulating layer IL1 at an uppermost portion of the first gate stack structure ST1 may be thicker than the first insulating layers IL1 below the first insulating layer IL1 at the uppermost portion. The second insulating layer IL2 at an uppermost portion of the second gate stack structure ST2 may be thicker than the second insulating layers IL2 below the second insulating layer IL2 at the uppermost portion. The uppermost first insulating layer IL1 of the first gate stack structure ST1 may be in contact with a lowermost second insulating layer IL2 of the second gate stack structure ST2.

The gate stack structure ST may extend from the cell array region CAR to the connection region CNR. The gate stack structure ST may have a stepped structure as shown in FIGS. 2 to 5 on the connection region CNR. A height of the stepped structure of the gate stack structure ST may decrease as getting farther away from the cell array region CAR. In other words, a height of the stepped structure of the gate stack structure ST may decrease from the cell array region CAR in a second direction D2. End portions of each of the electrodes EL may be exposed due to the stepped structure, and cell contact plugs CC may be connected to the end portions of each of the electrodes EL.

Among the electrodes EL of the gate stack structure ST, a pair of lowermost electrodes EL may be gate electrodes of the lower transistors LT1 and LT2 described with reference to FIG. 1, and a pair of uppermost electrodes EL may be gate electrodes of the upper transistors UT1 and UT2 described with reference to FIG. 1. The other electrodes EL except the two pairs of electrodes EL may be word lines.

The electrodes EL may each include at least one of doped semiconductor (for example, doped silicon), metal (for example, tungsten, copper, or aluminum), conductive metal nitride (for example, titanium nitride or tantalum nitride), or transition metal (for example, titanium or tantalum). The first and second insulating layers IL1 and IL2 may each include a silicon oxide layer.

A plurality of vertical structures VS penetrating the gate stack structure ST may be provided on the cell array region CAR. For example, referring to FIG. 5, four vertical structures VS may be arranged in a first direction D1 to form a first column C1, and five vertical structures VS may be arranged in the first direction D1 to form a second column C2. The first column C1 and the second column C2 may be repeatedly alternately arranged along the second direction D2. A diameter of each of the vertical structures VS may gradually decrease as getting closer to the second substrate SL. In some implementations, the vertical structures VS may include a step portion of which a diameter discontinuously changes at a boundary between the first gate stack structure ST1 and the second gate stack structure ST2.

Dummy structures DS penetrating the gate stack structure ST may be provided on the connection region CNR. The dummy structures DS may penetrate the stepped structure of the gate stack structure ST. In a plan view, a size (for example, maximum diameter) of each of the dummy structures DS may be greater than a size (for example, maximum diameter) of each of the vertical structures VS.

The vertical structures VS may be respectively provided in channel holes CH penetrating the gate stack structure ST. The vertical structures VS may each include an information storage layer FM, a vertical channel pattern SP, and a buried insulating pattern VI. The vertical channel pattern SP may be interposed between the information storage layer FM and the buried insulating pattern VI. A conductive pad PAD may be provided at an upper portion of each of the vertical structures VS. The vertical channel pattern SP may be spaced apart from the electrodes EL with the information storage layer FM therebetween.

The information storage layer FM may include a blocking insulating layer, a charge storage layer, and a tunneling insulating layer sequentially stacked on a sidewall of the channel hole CH. The blocking insulating layer may be adjacent to a stack structure or the second substrate SL, and the tunneling insulating layer may be adjacent to the vertical channel pattern SP. The charge storage layer may be interposed between the blocking insulating layer and the tunneling insulating layer. The blocking insulating layer, the charge storage layer, and the tunneling insulating layer may extend in the third direction D3 between the stack structure ST and the vertical channel pattern SP. A data storage pattern may store and/or change data due to a Fowler-Nordheim tunneling phenomenon induced by voltage difference between the electrodes EL and the vertical channel pattern SP. For example, the blocking insulating layer and the tunneling insulating layer may include silicon oxide, and the charge storage layer may include silicon nitride or silicon oxynitride.

The vertical channel pattern SP may include a semiconductor material such as silicon (Si), germanium (Ge), or mixture thereof. In addition, the vertical channel pattern SP may be impurity-doped semiconductor or intrinsic semiconductor in a state of not being doped with an impurity. For example, the vertical channel pattern SP may include polysilicon. In some implementations, the vertical channel pattern SP may include oxide semiconductor, such as IGZO. The vertical channel pattern SP including a semiconductor material may be used as a channel of transistors constituting a NAND cell string.

The conductive pad PAD may cover an upper surface of the vertical channel pattern SP and an upper surface of the buried insulating pattern VI. The conductive pad PAD may include an impurity-doped semiconductor material and/or a metal material. A first contact plug CT1 may be electrically connected to the vertical channel pattern SP through the conductive pad PAD.

The source semiconductor layer SSL may be in direct contact with a lower portion of each of the vertical channel patterns SP. The source semiconductor layer SSL may electrically connect a plurality of vertical channel patterns SP on the cell array region CAR to each other. In other words, the vertical channel patterns SP of the vertical structures VS may be electrically connected to the source semiconductor layer SSL. A common source voltage may be applied to the source semiconductor layer SSL. The source semiconductor layer SSL may horizontally extend and penetrate a lower portion of the information storage layer FM to be in contact with the vertical channel patterns SP. That is, the lower portion of the information storage layer FM may be separated from an upper portion with the source semiconductor layer SSL therebetween. The buried insulating pattern VI may include silicon oxide and/or silicon oxynitride.

The dummy structures DS may each include the information storage layer FM, the vertical channel pattern SP, and the buried insulating pattern VI, as in the above description of the vertical structures VS. The dummy structures DS may not function as a channel of a memory cell, unlike the vertical structures VS. The dummy structures DS may not be electrically connected to bit lines BL to be described later. That is, the dummy structures DS may be a dummy which does not have any function in terms of a circuit. The dummy structures DS may serve as a pillar (that is, support) which physically supports the stepped structure of the gate stack structure ST.

A plurality of separation structures SS penetrating the gate stack structure ST may be provided. The separation structures SS may be provided in trenches TR penetrating the gate stack structure ST. The trenches TR may expose an upper surface of the lower semiconductor layer LSL. The separation structures SS may extend in parallel to each other in the second direction D2. In a plan view, the separation structures SS may each have a bar shape or a line shape extending in the second direction D2. For example, first separation structures SS1 may each extend from the cell array region CAR to the connection region CNR, and one electrode EL may be horizontally separated into a plurality of electrodes EL. The first separation structures SS1 may extend between the gate stack structures ST and define the gate stack structures ST. For example, the first separation structures SS1 may extend between the gate stack structures ST as shown in FIG. 5.

For example, second separation structures SS2 may be provided in the connection region CNR and may have a shape of bars separated from each other in the second direction D2. The second separation structures SS2 may be provided in each of the gate stack structures ST. The separation structures SS may include an insulating material such as silicon oxide.

A second interlayer insulating layer 161, a third interlayer insulating layer 162, and bit lines BL may be sequentially provided on the gate stack structure ST. First contact plugs CT1 connected to the vertical structures VS may be provided in the second interlayer insulating layer 161. Second contact plugs CT2 connecting the first contact plugs CT1 and the bit lines BL may be provided in the third interlayer insulating layer 162. The second and third interlayer insulating layers 161 and 162 may include silicon oxide. The bit lines BL may extend in parallel to each other in the first direction D1. A plurality of upper lines may be disposed on the cell contact plugs CC. In some implementations, the bit lines BL and the upper lines may be electrically connected to the lower lines INL of the peripheral circuit structure PS through penetration contacts.

A residual sacrificial layer SC1r may be provided between the vertical structures VS and an uppermost insulating layer among the first insulating layers IL1 of the first gate stack structure ST1. The residual sacrificial layer SC1r may be provided to be adjacent to an interface between the gate stack structures. For example, the residual sacrificial layer SC1r may be provided, at a position at which the uppermost first insulating layer IL1 of the first gate stack structure ST1 and the lowermost second insulating layer IL2 of the second gate stack structure ST2 are connected, on the uppermost first insulating layer IL1 defining an inner sidewall of first channel holes CH1. In a case in which the second gate stack structure ST2 is the highest gate stack structure, the residual sacrificial layer SC1r may not be provided in the second gate stack structure ST2.

In a case in which a third gate stack structure is provided on the second gate stack structure ST2, the residual sacrificial layer SC1r may be additionally provided between and adjacent to the second gate stack structure ST2 and the third gate stack structure. In this case, a residual sacrificial layer may not be provided in the third gate stack structure which is the highest structure, and the residual sacrificial layer SC1r may be provided in the second gate stack structure ST2 and the first gate stack structure ST1 only.

An interface between the uppermost first insulating layer IL1 of the first gate stack structure ST1 and the lowermost second insulating layer IL2 of the second gate stack structure ST2 may be observed, but alternatively, may not be observed.

A position of the residual sacrificial layer SC1r may be described on the basis of a cross-sectional shape of the vertical structures VS. The vertical structures VS may include a step portion which is adjacent to an interface between the gate stack structures and of which a diameter discontinuously changes, and the residual sacrificial layer SC1r may be provided on an outer sidewall of the step portion as shown in FIG. 7. In a plan view, the residual sacrificial layer SC1r may have a shape of a ring or a partial shape of a ring formed along an outer side surface of the vertical structure VS.

In FIG. 6, the gate stack structure ST is disposed between the bit lines BL and the peripheral circuit structure PS, but in some implementations, the bit lines BL and the upper lines may be disposed between the gate stack structure ST and the peripheral circuit structure PS. In this case, connection of the peripheral circuit structure PS and the cell array structure CS may be in a form described with reference to FIGS. 3 and 4.

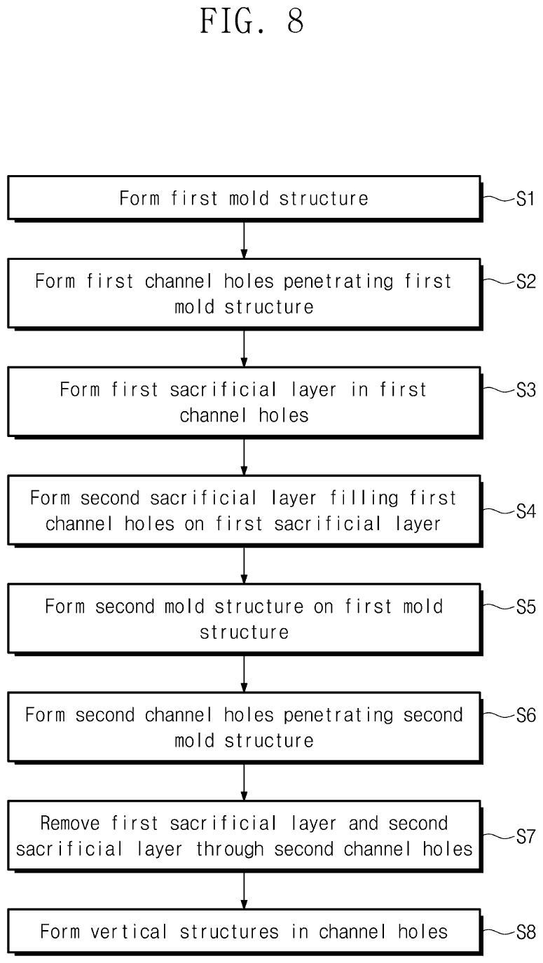

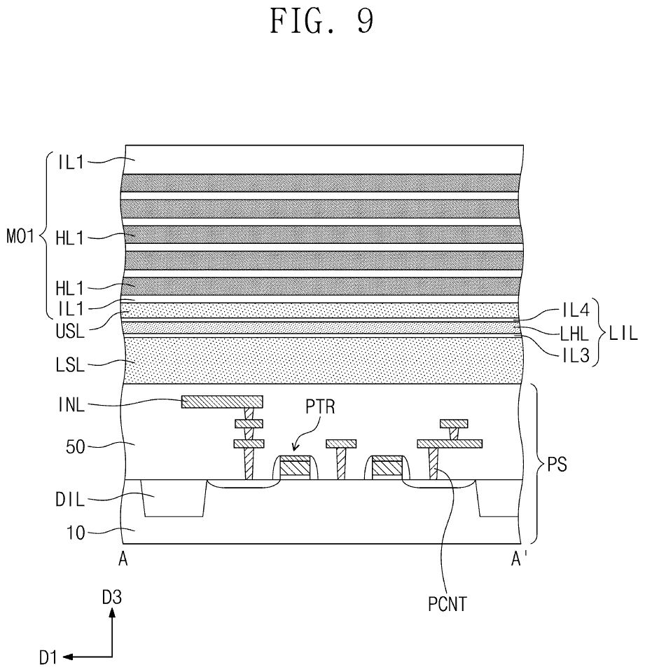

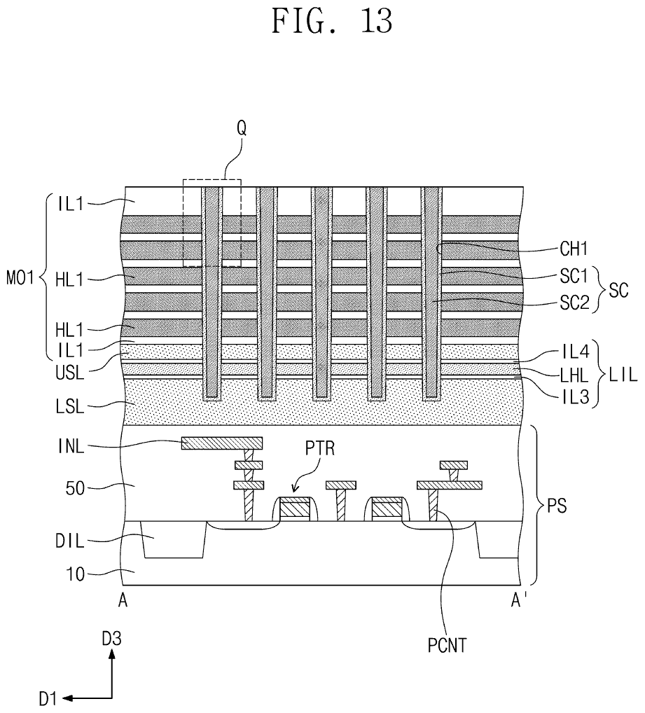

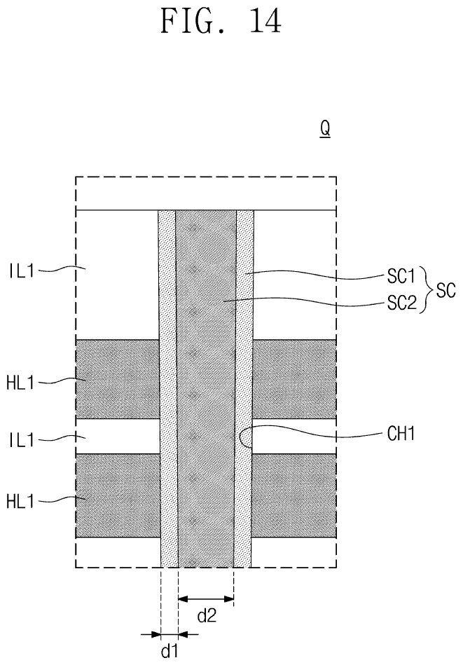

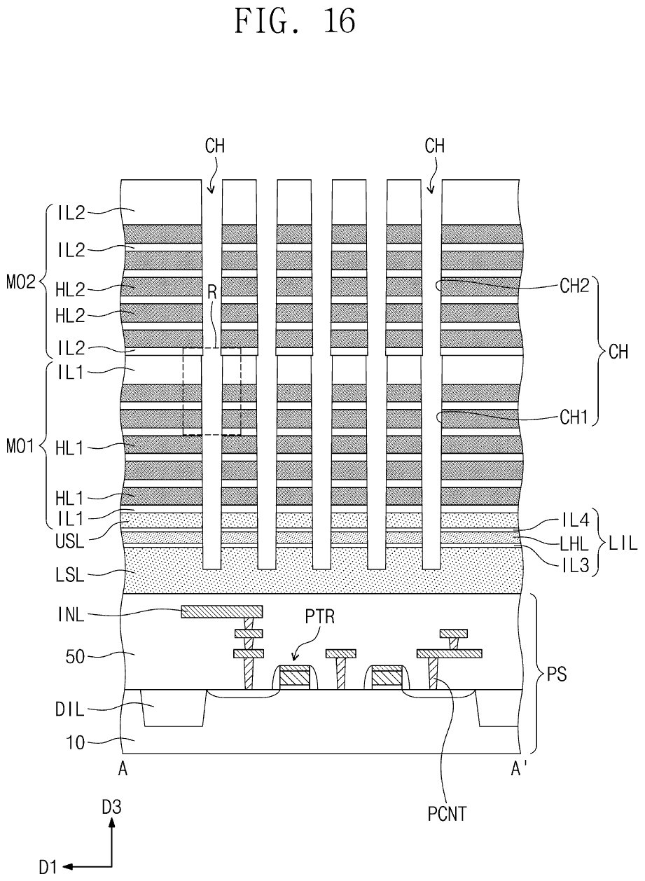

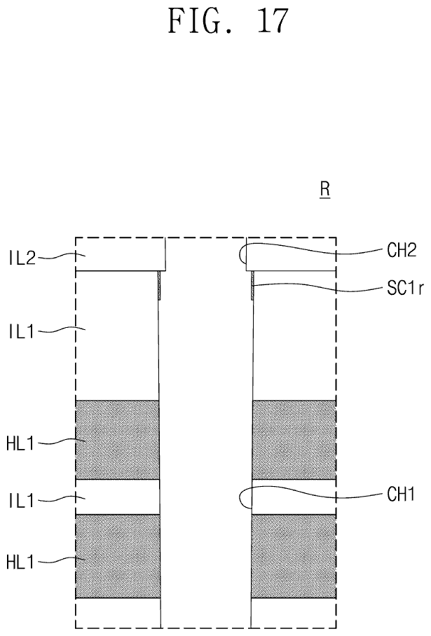

FIG. 8 is a process flowchart illustrating an example of a method of manufacturing a semiconductor device according to some implementations. FIGS. 9 to 13, 15, 16, 18, and 19 are cross-sectional views taken along line A-A′ of FIG. 5, for describing an example of a method of manufacturing a semiconductor device according to some implementations. FIG. 14 is an enlarged view of region Q of FIG. 13 according to some implementations. FIG. 17 is an enlarged view of region R of FIG. 16 according to some implementations.

In FIGS. 8 and 9, a peripheral circuit structure PS may be formed on a first substrate 10. Forming the peripheral circuit structure PS may include forming peripheral transistors PTR on the first substrate 10 and forming lower lines INL on the peripheral transistors PTR. For example, forming the peripheral transistors PTR may include forming an element isolation layer D1L defining active regions on the first substrate 10, forming a gate insulating layer and a gate electrode on the active regions, and forming a source/drain region by injecting an impurity to the active regions. A first interlayer insulating layer 50 covering the peripheral transistors PTR and the lower lines INL may be formed.

A lower semiconductor layer LSL may be formed on the first interlayer insulating layer 50. For example, the lower semiconductor layer LSL may include a semiconductor material such as polysilicon. An insulating structure LIL may be formed on the lower semiconductor layer LSL. Forming the insulating structure LIL may include sequentially forming a lower insulating layer IL3, a lower sacrificial layer LHL, and an upper insulating layer IL4 on the lower semiconductor layer LSL. The lower and upper insulating layers IL3 and IL4 may include a silicon oxide layer, and the lower sacrificial layer LHL may include a silicon nitride layer or a silicon oxynitride layer.

An upper semiconductor layer USL may be conformally formed on the insulating structure LIL. For example, the upper semiconductor layer USL may include a semiconductor material, such as polysilicon.

A first mold structure MO1 may be formed on the upper semiconductor layer USL (S1). In detail, the first mold structure MO1 may be formed by alternately stacking first insulating layers IL1 and third insulating layers HL1 on the upper semiconductor layer USL. The first insulating layer IL1 may be formed at an uppermost portion of the first mold structure MO1. The first insulating layers IL1 and the third insulating layers HL1 may be deposited using a thermal chemical vapor deposition (thermal CVD) process, a plasma enhanced chemical vapor deposition (plasma enhanced CVD) process, a physical chemical vapor deposition (physical CVD) process, or an atomic layer deposition (ALD) process. The first insulating layers IL1 may include a silicon oxide layer, and the third insulating layers HL1 may include a silicon nitride layer or a silicon oxynitride layer.

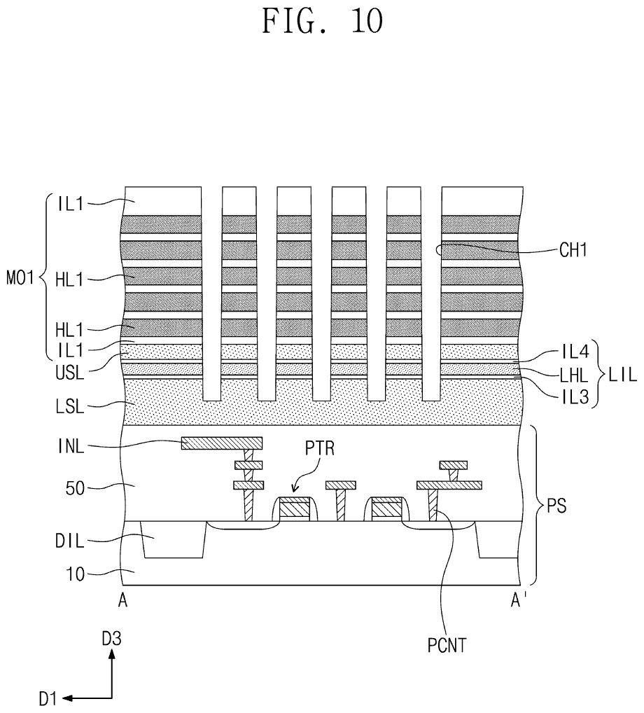

In FIGS. 8 and 10, first channel holes CH1 penetrating the first mold structure MO1 may be formed (S2). Lower portions of the first channel holes CH1 may penetrate the insulating structure LIL. The first channel holes CH1 may be formed through an anisotropic etching process. The anisotropic etching process may include a plasma etching process, a reactive ion etching (RIE) process, an inductively coupled plasma reactive ion etching (ICP-RIE) process, or an ion beam etching (IBE) process. Lower portions of the first channel holes CH1 may be formed in the lower semiconductor layer LSL.

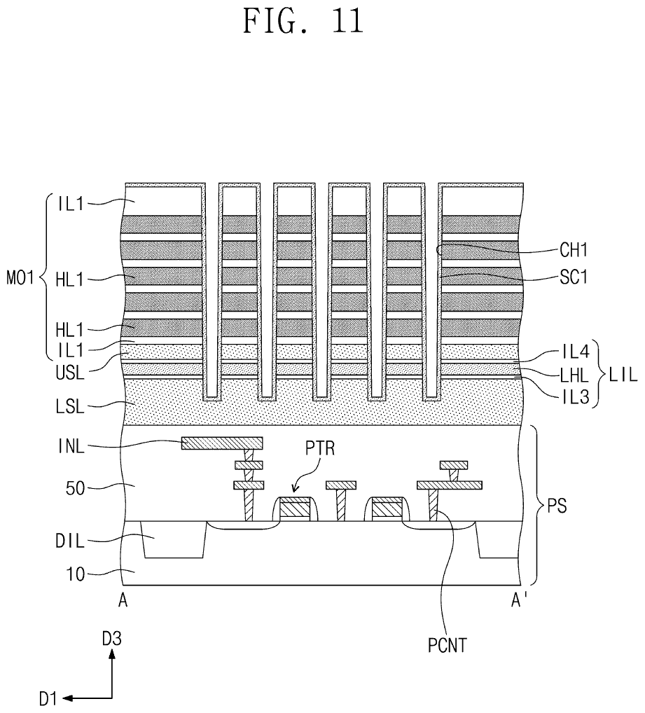

In FIGS. 8 and 11, a first sacrificial layer SC1 may be formed in the first channel holes CH1 (S3). The first sacrificial layer SC1 may be conformally formed along inner sidewalls of the first channel holes CH1 and an upper surface of an uppermost first insulating layer IL1. The first sacrificial layer SC1 may be formed by chemical vapor deposition, for example, plasma enhanced chemical vapor deposition (PECVD). A first deposition process of forming the first sacrificial layer SC1 may include supplying a carbon source and a nitrogen source. The carbon source for forming the first sacrificial layer SC1 may include acetylene (C₂H₂) gas. The nitrogen source for forming the first sacrificial layer SC1 may include ammonia (NH₃) gas and/or nitrogen (N₂) gas. The first deposition process of forming the first sacrificial layer SC1 may include supplying inert gas such as argon (Ar).

The first sacrificial layer SC1 may include a carbon nitride layer. The first sacrificial layer SC1 may include a CxNy layer (x and y are constants). An atomic ratio (based on a ratio of constituent component's atomic percentage (at %)) of nitrogen to carbon of the first sacrificial layer SC1 may be about 0.7 to about 1.3. A carbon content of the first sacrificial layer SC1 may be about 30 at % to about 70 at %. A nitrogen content of the first sacrificial layer SC1 may be about 30 at % to about 70 at %. The first sacrificial layer SC1 may not include silicon if diffusion in an adjacent layer or an impurity is excluded.

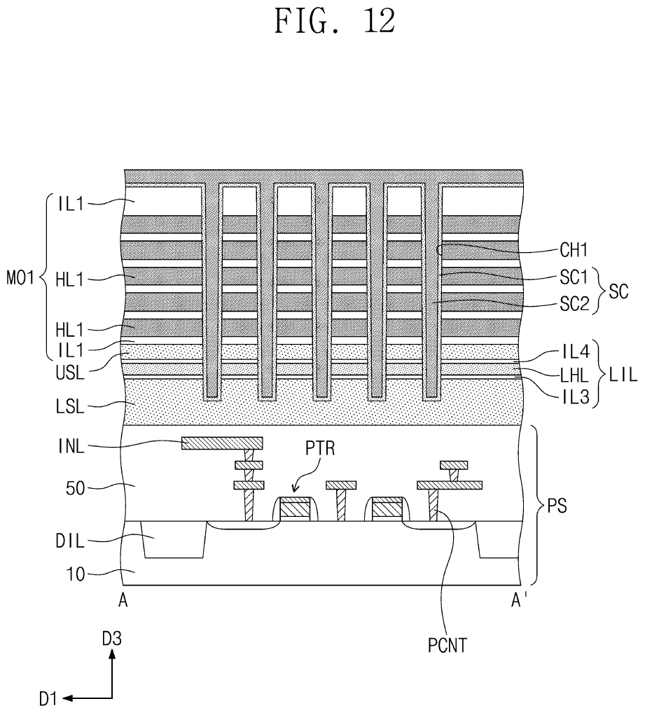

In FIGS. 8 and 12, a second sacrificial layer SC2 which fills the first channel holes CH1 may be formed on the first sacrificial layer SC1 (S4). The second sacrificial layer SC2 may fill the remaining space of the first channel holes CH1 in which the first sacrificial layer SC1 is formed. The second sacrificial layer SC2 may be formed by chemical vapor deposition, for example, plasma enhanced chemical vapor deposition (PECVD). A second deposition process for forming the second sacrificial layer SC2 and the first deposition process for forming the first sacrificial layer SC1 may be continuously performed in the same process chamber. For example, during in-situ processing, multiple layers may be continuously formed within the same process chamber, with the source material being changed and while maintaining a vacuum state within the process chamber. The second deposition process may include supplying a carbon source but may not include supplying a nitrogen source. The carbon source for forming the second sacrificial layer SC2 may include acetylene (C₂H₂) gas. The second deposition process for forming the second sacrificial layer SC2 may include supplying hydrogen (H₂) gas. The second deposition process for forming the second sacrificial layer SC2 may include supplying inert gas such as argon (Ar).

The second sacrificial layer SC2 may include a carbon layer. A carbon content of the second sacrificial layer SC2 may be about 90 at % or more. A nitrogen content of the second sacrificial layer SC2 may be less than about 5 at %. The second sacrificial layer SC2 may not include silicon if diffusion in an adjacent layer or an impurity is excluded.

The first deposition process for forming the first sacrificial layer SC1 may be performed under first pressure, and the second deposition process for forming the second sacrificial layer SC2 may be performed under second pressure higher than the first pressure. The first deposition process for forming the first sacrificial layer SC1 may be performed at first RF power, and the second deposition process for forming the second sacrificial layer SC2 may be performed at second RF power greater than the first RF power. The first deposition process and the second deposition process may be performed at substantially the same temperature.

In FIGS. 13 and 14, a planarization process may be performed until an upper surface of the uppermost first insulating layer IL1 is exposed. As a result, the first and second sacrificial layers SC1 and SC2 may become sacrificial patterns SC separated in the first channel holes CH1. The planarization process may include chemical mechanical polishing. The first sacrificial layer SC1 and the second sacrificial layer SC2 constituting the sacrificial patterns SC may each be an amorphous layer. A thickness d2 of the second sacrificial layer SC2 may be about five times to about fifteen times a thickness d1 of the first sacrificial layer SC1. For example, a first thickness d1 may be about 3 nm to about 15 nm. A second thickness d2 may be about 15 nm to about 150 nm.

The first sacrificial layer SC1 has excellent adhesiveness with the first mold structure MO1, particularly the first insulating layers IL1 constituting the first mold structure MO1, compared to the second sacrificial layer SC2. This may result from relatively high nitrogen concentration of the first sacrificial layer SC1. In addition, the first sacrificial layer SC1 also has excellent adhesiveness with the second sacrificial layer SC2, which results from relatively high nitrogen concentration.

A wet etching process may be performed on the first mold structure MO1, in which the sacrificial patterns SC are formed, before forming a second mold structure to be described below. For example, the wet etching process may be part of the planarization process or part of a process for forming an align key. A buffered oxide etch (BOE) solution or a phosphoric acid solution may be used in the wet etching process. Such etching materials of the wet etching process may infiltrate into the first mold structure MO1 through an upper portion of the first mold structure MO1, more specifically, an interface between the first mold structure MO1 and the sacrificial patterns SC. Accordingly, partial loss of the third insulating layers HL1 may occur due to a wet etching material.

According to some implementations, since the sacrificial patterns SC include the first sacrificial layer SC1 having excellent adhesiveness with the first insulating layers IL1, loss of the third insulating layers HL1 described above may be prevented, and thus yield and reliability of a semiconductor device may be improved.

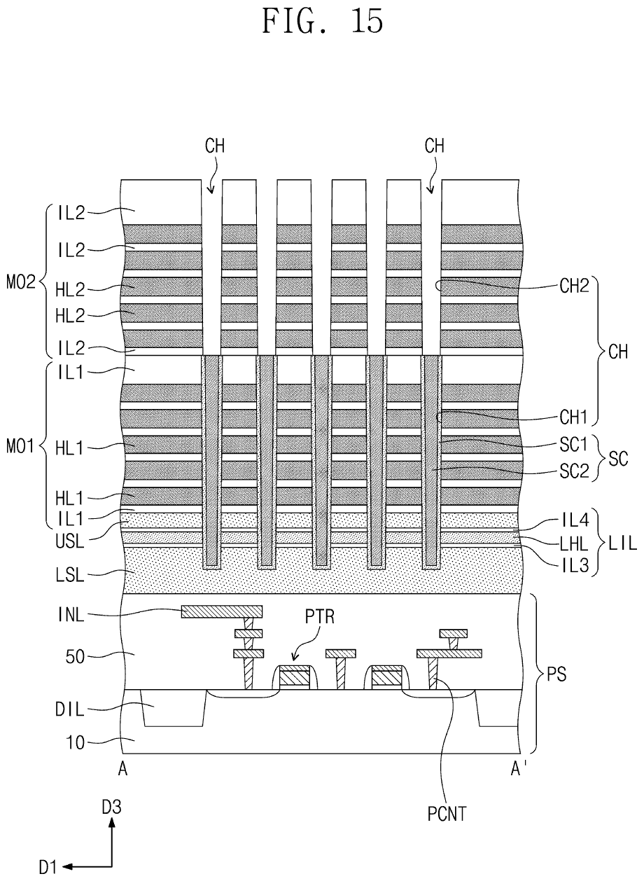

In FIGS. 8 and 15, a second mold structure MO2 may be formed on the first mold structure MO1 (S5). The second mold structure MO2 may be formed by alternately depositing second insulating layers IL2 and fourth insulating layers HL2. The second insulating layers IL2 may include the same material as that of the first insulating layers IL1. The fourth insulating layers HL2 may include the same material as that of the third insulating layers HL1. An uppermost second insulating layer IL2 may be formed to be thicker than the second insulating layers IL2 below the uppermost second insulating layer IL2.

Second channel holes CH2 penetrating the second mold structure MO2 may be formed (S6). The second channel holes CH2 may expose upper surfaces of the sacrificial patterns SC. Hereinafter, a structure in which the first channel holes CH1 and the second channel holes CH2 are connected is referred to as channel holes CH.

In FIGS. 8, 16, and 17, the sacrificial patterns SC may be selectively removed through the second channel holes CH2 (S7). Selectively removing the sacrificial patterns SC may be performed with an etchant including hydrofluoric acid. When the sacrificial patterns SC are selectively removed, a portion of the first sacrificial layer SC1 may not be removed and may remain at an upper portion of the first channel holes CH1. That is, a residual sacrificial layer SC1r may be formed at a portion of the channel holes CH. The residual sacrificial layer SC1r may be provided to be adjacent to an interface between the first mold structure MO1 and the second mold structure MO2. The residual sacrificial layer SC1r may remain at a portion of a step portion, as in FIG. 17, in a portion in which the first channel holes CH1 and the second channel holes CH2 are connected, that is, the step portion in which a diameter of the channel hole CH discontinuously changes.

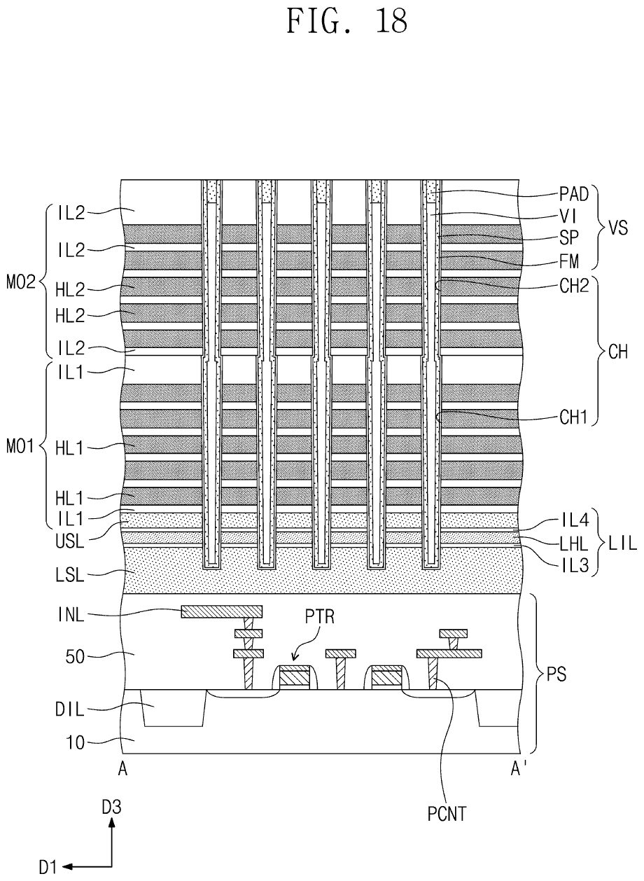

In FIGS. 8 and 18, vertical structures VS may be formed in the channel holes CH (S8). Forming the vertical structures VS may include forming an information storage layer FM, a vertical channel pattern SP, and a buried insulating pattern VI, which sequentially cover inner sidewalls of the channel holes CH, and forming a conductive pad PAD thereon.

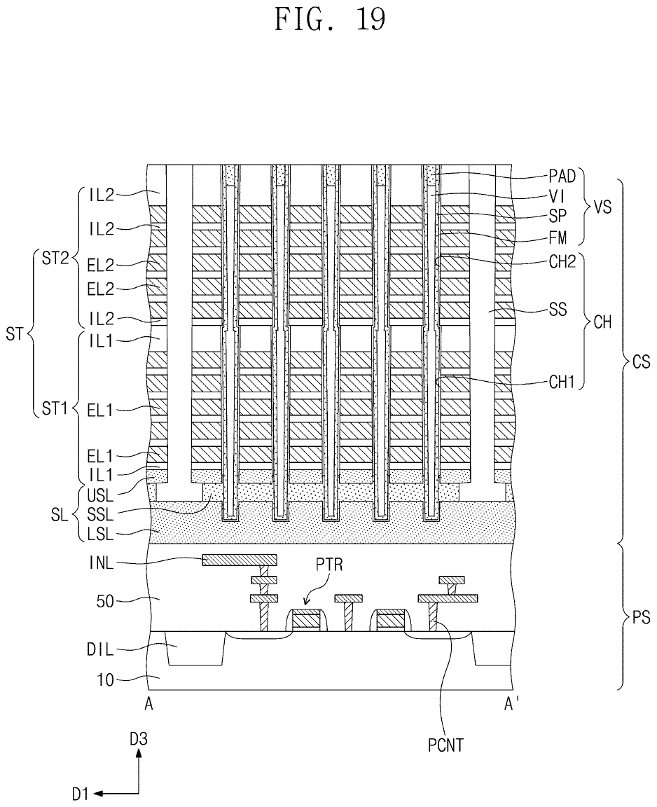

In FIG. 19, trenches TR penetrating the second mold structure MO2 and the first mold structure MO1 may be formed. The trenches TR may extend along the second direction D2 so as to correspond to a shape of the separation structures SS described with reference to FIG. 5. Lower portions of the trenches TR may expose the lower sacrificial layer LHL. Forming the trenches TR may include an anisotropic etching process.

The lower sacrificial layer LHL exposed by the trenches TR may be replaced with a source semiconductor layer SSL. In detail, the lower sacrificial layer LHL may be selectively removed due to the trenches TR. A lower portion of the information storage layer FM may be exposed as the lower sacrificial layer LHL is removed. An undercut region may be formed by removing the exposed lower portion of the information storage layer FM. The undercut region may expose a lower portion of the vertical channel pattern SP. The lower insulating layer IL3 and the upper insulating layer IL4 may be removed together during removing the lower portion of the information storage layer FM. The source semiconductor layer SSL may be formed in a space in which the insulating structure LIL is removed. The source semiconductor layer SSL may be in contact with the vertical channel pattern SP.

Gate stack structures ST may be formed by respectively replacing the third and fourth insulating layers HL1 and HL2 exposed by the trenches TR with electrodes EL. In detail, the third and fourth insulating layers HL1 and HL2 exposed through the trenches TR may be selectively removed. The electrodes EL may be respectively formed in spaces in which the third and fourth insulating layers HL1 and HL2 are removed. That is, the third insulating layers HL1 may be replaced with first electrodes EL1, and the fourth insulating layers HL2 may be replaced with second electrodes EL2. Separation structures SS may be formed in the trenches TR by filling the trenches TR with an insulating material. The separation structure SS may include silicon oxide.

In FIGS. 5 to 7, a second interlayer insulating layer 161 and first and second contact plugs CT1 and CT2 penetrating the second interlayer insulating layer 161 may be formed on the separation structure SS. A third interlayer insulating layer 162 and vias VA penetrating the third interlayer insulating layer 162 may be formed on the second interlayer insulating layer 161. Thereafter, bit lines BL may be formed on the third interlayer insulating layer 162. Wiring layers may be formed on the bit lines BL.

According to some implementations, a sacrificial pattern including a first sacrificial layer having relatively great adhesiveness with a mold structure may prevent partial loss of the mold structure due to a wet etching process.

According to some implementations, a semiconductor device with more improved yield and reliability may be provided.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A method of manufacturing a semiconductor device, the method comprising:
forming a first mold structure that includes first insulating layers and third insulating layers, wherein the first insulating layers and third insulating layers are alternately provided on a substrate;
forming a plurality of first channel holes extending into the first mold structure;
forming a first sacrificial layer in the plurality of first channel holes;
forming, on the first sacrificial layer, a second sacrificial layer that fills the plurality of first channel holes;
forming a second mold structure that includes a plurality of second insulating layers and a plurality of fourth insulating layers, wherein the plurality of second insulating layers and the plurality of fourth insulating layers are alternately provided on the first mold structure;
forming a plurality of second channel holes extending into the second mold structure;
removing, through the plurality of second channel holes, the first sacrificial layer and the second sacrificial layer in the first channel holes; and
forming a vertical structure in the plurality of first channel holes and the plurality of second channel holes,
wherein the first sacrificial layer includes a carbon nitride layer, and
wherein the second sacrificial layer includes a carbon layer.

2. The method of claim 1, wherein an atomic ratio of nitrogen to carbon within the first sacrificial layer is about 0.7 to about 1.3.

3. The method of claim 1, wherein a carbon content of the second sacrificial layer is about 90 atomic percent or more.

4. The method of claim 1,
wherein a carbon content of the first sacrificial layer is about 30 at % to about 70 at %, and
wherein a nitrogen content of the first sacrificial layer is about 30 at % to about 70 at %.

5. The method of claim 1, wherein the first sacrificial layer and the second sacrificial layer comprise an amorphous layer.

6. The method of claim 1, wherein a thickness of the second sacrificial layer is about five times to about fifteen times greater than a thickness of the first sacrificial layer.

7. The method of claim 1, wherein the first sacrificial layer and the second sacrificial layer are continuously formed in a same process chamber.

8. The method of claim 1, wherein the first sacrificial layer and the second sacrificial layer are formed in a plasma enhanced chemical vapor deposition (PECVD) process.

9. The method of claim 1, wherein forming the first sacrificial layer and the second sacrificial layer comprises supplying a carbon source including C₂H₂ to a process chamber.

10. The method of claim 9, wherein forming the first sacrificial layer and forming the second sacrificial layer comprise supplying a nitrogen source including NH₃ and/or N₂ to a process chamber.

11. The method of claim 1,
wherein forming the first sacrificial layer comprises performing a first deposition process under a first pressure, and
wherein the forming the second sacrificial layer comprises performing a second deposition process under a second pressure that is higher than the first pressure.

12. The method of claim 1,
wherein forming the first sacrificial layer comprises performing a first deposition process at a first RF power, and
wherein the forming of the second sacrificial layer comprises performing a second deposition process at a second RF power that is greater than the first RF power.

13. The method of claim 1, comprising performing a planarization process before forming the second mold structure and after forming the second sacrificial layer.

14. A method of manufacturing a semiconductor device, the method comprising:
forming a first mold structure that includes a plurality of first insulating layers and a plurality of third insulating layers, wherein the plurality of first insulating layers and the plurality of third insulating layers are alternately provided on a substrate;
forming a plurality of first channel holes extending into the first mold structure;
forming a plurality of sacrificial patterns in the plurality of first channel holes, respectively;
forming a second mold structure that includes a plurality of second insulating layers and a plurality of fourth insulating layers, wherein the plurality of second insulating layers and the plurality of fourth insulating layers are alternately provided on the first mold structure;
forming a plurality of second channel holes extending into the second mold structure;
removing the plurality of sacrificial patterns in the plurality of first channel holes through the plurality of second channel holes; and
forming a vertical structure in the plurality of first channel holes and the plurality of second channel holes,
wherein the forming of the plurality of sacrificial patterns includes
performing a first deposition process that comprises supplying a nitrogen source and a carbon source, and
performing a second deposition process that comprises supplying the carbon source without supplying the nitrogen source.

15. The method of claim 14,
wherein performing the first deposition process comprises forming a first sacrificial layers,
wherein performing the second deposition process comprises forming a second sacrificial layer, and
wherein the second sacrificial layer is thicker than the first sacrificial layer.

16. The method of claim 15, wherein an atomic ratio of nitrogen to carbon of the first sacrificial layer is about 0.7 to about 1.3.

17. The method of claim 15, wherein a carbon content of the second sacrificial layer is about 90 at % or more.

18. The method of claim 15,
wherein a carbon content of the first sacrificial layer is about 30 at % to about 70 at %, and
wherein a nitrogen content of the first sacrificial layer is about 30 at % to about 70 at %.

19. The method of claim 15, wherein the first sacrificial layer and the second sacrificial layer are continuously formed in a same process chamber.

20. The method of claim 15, wherein the first sacrificial layer and the second sacrificial layer comprise an amorphous layer.
